(19) United States
(12) Patent Application Publication
(10) Pub. No.: US 2007/0235872 A1
(43) Pub. Date: Oct. 11, 2007

(54) SEMICONDUCTOR PACKAGE STRUCTURE

(76) Inventor: Ping-Chang Wu, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/277,617

(22) Filed: Mar. 28, 2006

(51) Int. Cl. H01L 23/48; H01L 23/52; H01L 29/40

(52) U.S. Cl. 257/738

(57) ABSTRACT

A semiconductor package structure includes a semiconductor chip on which an electrical connection region having a plurality of chip bonding pads and a non-electrical connection region are defined, a substrate having a plurality of substrate bonding pads respectively corresponding to the chip bonding pads on a surface facing the semiconductor chip, a chip holder used for supporting the semiconductor chip, and a plurality of intermediate resilient conductive elements for electrically connecting the semiconductor chip to the substrate.

### BACKGROUND OF THE INVENTION

1. Field of the Invention

The invention relates to a semiconductor package structure, and more particularly, to a semiconductor package structure for avoiding delamination problem caused by thermal expansion coefficient (CTE) mismatch.

2. Description of the Prior Art

Following the ever-present demand for decreasing the sizes and geometries of electronic components and the high-standard requirement for amounts of I/O terminals, thermal dissipation, and miniaturization in IC encapsulating technology, the demands on flip chip (FC) packaging are continually rising.

Please refer to FIG. 1 which is a sectional drawing of a conventional flip chip package structure. As shown in FIG. 1, a conventional flip chip package structure 10 comprises a chip 12 having a plurality of bonding pads 14 formed on one of its surfaces. The flip chip package structure 10 further comprises a substrate 16 having a plurality of bonding pads 18 formed on one of its surfaces. The electrical connection is achieved by a plurality of solder balls 20 between the bonding pads 14 and bonding pads 18. Furthermore, the flip chip package structure 10 also comprises a sealing material 22 filling the space between the solder balls 20, the substrate 16, and the chip 12 to protect the flip chip package structure 10 from damage and absorb the stress on junctions of the solder balls 20. In addition, the flip chip package structure 10 comprises a ball grid array (BGA) 24 for transferring the input/output signals.

However, because the thermal expansion coefficient (CTE) mismatch between the chip 12 and the substrate 16 of the conventional flip chip package structure 10 is significant, the flip chip package structure is easily affected by thermo-mechanical stress generated from thermal cycles during operation. The thermo-mechanical stress is absorbed by the bonding pads 14, the solder balls 20, and the bonding pads 18, and can cause failure of solder balls 20, cracking, or delamination in the chip edge, especially in a corner. Therefore the reliability of the flip chip package structure 10 is seriously affected.

To resolve the abovementioned problems, there have been many solutions provided in prior art, such as filling the space between the solder balls, the chip, and the substrate with elastic materials such as epoxy resin to improve the absorption of thermo-mechanical stress and reduce the failure of the solder joints caused by CTE mismatch. But this method suffers from long filling processes, incomplete filling, or air entrapment. Therefore encapsulating processes are more complicated and the sealing material itself becomes a bottleneck concerning with the high-density demand for devices and I/O terminals. Prior art also provides a method to intentionally form sacrificial solder joints or redundancy terminals in the locations where the thermo-mechanical stress is highest. But this method consumes valuable space on the chip and it thus expensive. Finally, there is another method provided by prior art: replacing the solder balls with flexible bonding wires. The bending sections of the bonding wires provide a resilience to absorb the thermo-mechanical stress caused by CTE mismatch. However, such kind of bonding wires cannot bear the chip as the solder balls do, and the package structure necessarily needs a sealing material to support and strengthen the entire package structure.

### SUMMARY OF THE INVENTION

Therefore, it is an object of the present invention to provide a semiconductor package structure for avoiding problems such as delamination caused by CTE mismatch.

According to the claimed invention, a semiconductor package structure is provided. The semiconductor package structure comprises a semiconductor chip on which an electrical connection having a plurality of chip bonding pads there-within and a non-electrical connection region are defined, a substrate having a plurality of substrate bonding pads corresponding to the chip bonding pads on a surface facing the semiconductor chip, a chip holder formed on the substrate and corresponding to the non-electrical connection region for sustaining the semiconductor chip, and a plurality of intermediate resilient conductive elements formed in between the chip bonding pads and the substrate bonding pads for electrically connecting the semiconductor chip to the substrate.

According to the claimed invention, another semiconductor package structure is provided. The semiconductor package structure comprises a first package structure and a second package structure. The first package structure comprises a first substrate on which an electrical connection region having a plurality of first substrate bonding pads there-within and a non-electrical connection region are defined and at least a first chip on the first substrate. The second package structure is below the first package structure and comprises a second substrate and at least a second chip formed on a surface of the second substrate. The semiconductor package structure provided by the invention further comprises a holder formed on the second substrate and corresponding to the non-electrical connection region for sustaining the first package structure and a plurality of intermediate resilient conductive elements formed in between the first package structure and the second package structure for providing an electrical connection between the first package structure and the second package structure.

According to the semiconductor package structure provided by the claimed invention, the chip holder is used to support the chip or the first package and the intermediate resilient conductive elements are used to absorb the thermo-mechanical stress caused during operation. Therefore, the semiconductor package structure avoids problems such as failure of solder balls, cracking, and delamination caused by CTE mismatch without affecting the amounts and the density of I/O terminals.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional drawing of a conventional flip chip package.

FIGS. 2-5 are schematic drawings of a semiconductor package structure and its components according to one of the preferred embodiments of the present invention.

FIGS. 6-9 are schematic drawings of a semiconductor package structure and its components according to another preferred embodiment of the present invention.

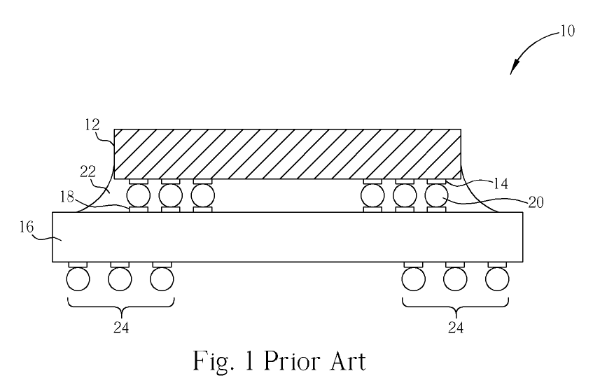

### DETAILED DESCRIPTION

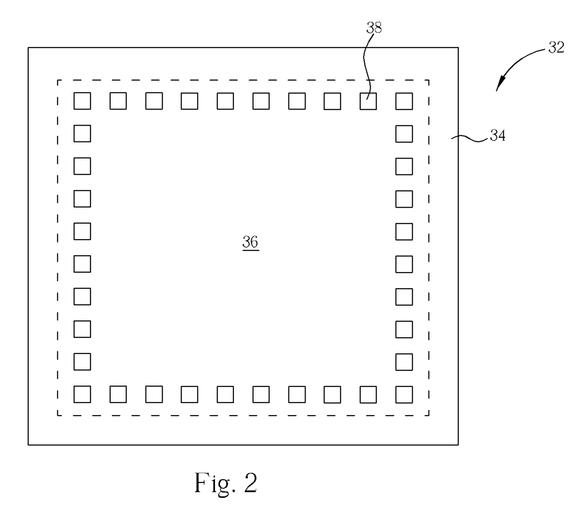

Please refer to FIGS. 2-5 which are schematic drawings of a semiconductor package structure and its components according to one of the preferred embodiments of the present invention. As shown in FIG. 2, a semiconductor package structure 30 comprising a semiconductor chip 32 such as a flip chip is provided. A non-electrical connection region 34 and an electrical connection region 36 are defined on a surface of the semiconductor chip 32. The semiconductor chip 32 further comprises a plurality of chip bonding pads 38 formed in the electrical connection region 36.

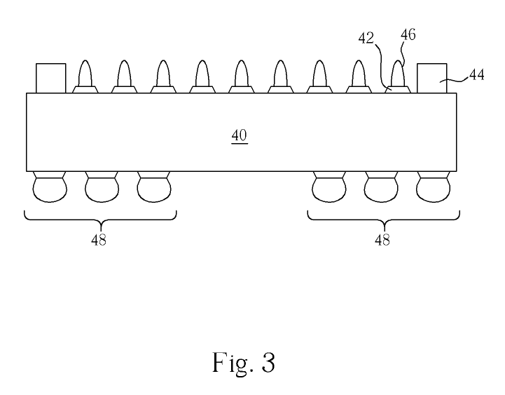

Please refer to FIG. 3. The semiconductor package structure 30 comprises a substrate 40 having a plurality of substrate bonding pads 42 formed on a surface facing the semiconductor chip 32. The substrate bonding pads 42 correspond to the chip bonding pads 38. The semiconductor package structure 30 further comprises a chip holder 44 formed on the substrate 44 by an adhesion material (not shown) for supporting the semiconductor chip 32. The semiconductor package structure 30 also comprises a plurality of intermediate resilient conductive elements 46 formed on the substrate bonding pads 42. In addition, the substrate 40 comprises a BGA 48 on the other surface for transferring the input/output signals.

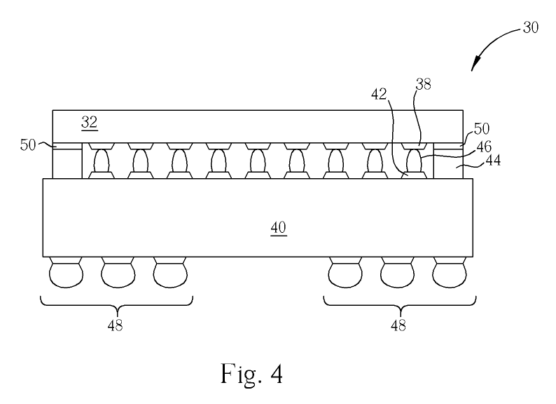

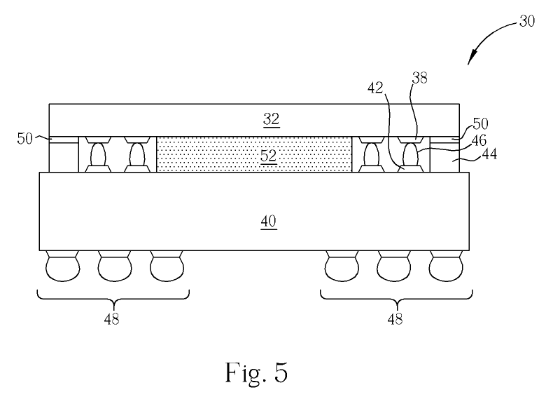

Next, please refer to FIG. 4. The semiconductor chip 44 is adhered to the chip holder 44 by an adhesion layer 50. Each of the substrate bonding pads 42 is electrically connected to the corresponding chip bonding pad 38 through at least one intermediate resilient conductive element 46. In other words, the electrical connection between the semiconductor chip 32 and the substrate 40 is provided by the intermediate resilient conductive elements 46. Furthermore, as shown in FIG. 5, the semiconductor package structure 30 can further comprise a moisture absorbing material 52 such as a moisture-adsorbing resin between the semiconductor chip 32 and the substrate 40 for protecting the intermediate resilient conductive elements 46 from moisture, which affects electrical performance, depending on the standard of design and required function of the product.

It is noteworthy that the intermediate resilient conductive elements 46 are formed by metal wire bonds, each having a flexible part for contacting the chip bonding pads 38. The chip holder 44 comprising insulating material is corresponding to the non-electrical connection region 34 of the semiconductor chip 32 and can be a ring holder surrounding the intermediate resilient conductive elements 46, the chip bonding pads 38, and the substrate bonding pads 42. The ring holder 44 can comprise a plurality of openings depending on different demands. Such openings can be an injection hole for moisture absorbing material or sealing material or a dissipation hole. More significant, the chip holder 44 has a thickness substantially smaller than heights of the intermediate resilient conductive elements 46. When the semiconductor chip 32 is adhered to the chip holder 44 by the adhesion layer 50, each chip bonding pad 38 will be against the flexible part of each intermediate resilient conductive element 46 and will slightly press the intermediate resilient conductive element 46 down. Therefore the electrical connection between the semiconductor chip 32 and the substrate 40 is provided and assured.

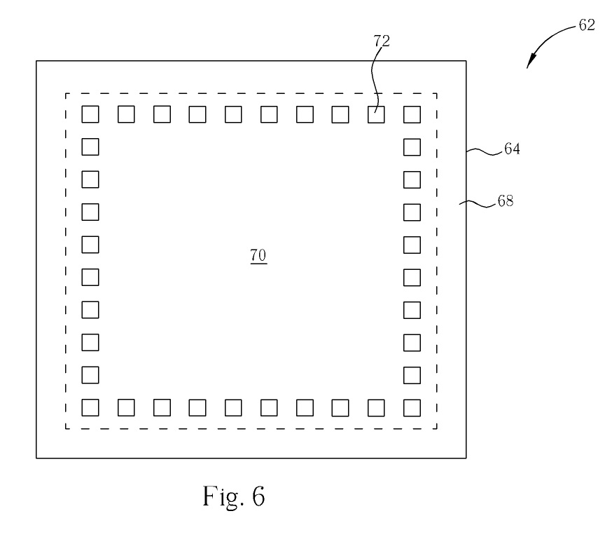

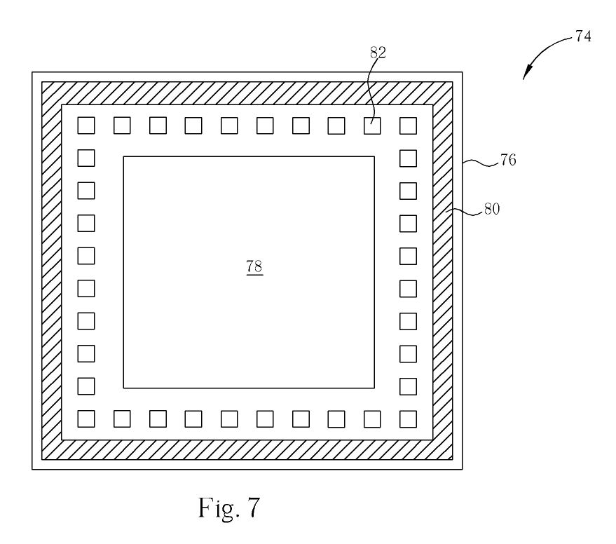

Please refer to FIGS. 6-9 which are schematic drawings of a semiconductor package structure and its components according to another preferred embodiment of the present invention. As shown in FIG. 6, a semiconductor package structure 60 comprises a first package structure 62. The first package structure 62 comprises a first substrate 64 having a chip 66 (shown in FIG. 7) on a surface and a non-electrical connection 68 and an electrical connection region 70 defined on the other surface. The electrical connection region 70 comprises a plurality of first substrate bonding pads 72 there-within.

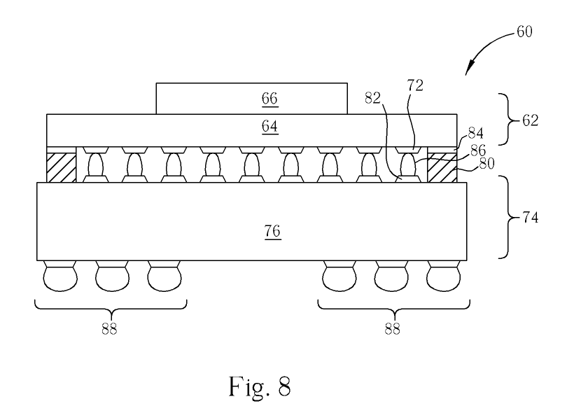

Please refer to FIG. 7. The semiconductor package structure 60 also comprises a second package structure 74. The second package structure 74 comprises a second substrate 76 having at least a second chip 78 and a plurality of second substrate bonding pads 82 corresponding to the first substrate bonding pads 72 formed on a surface facing the first package structure 60. Furthermore, the semiconductor package structure 60 comprises a holder 80 corresponding to the non-electrical connection region 68 of the first substrate 64 for supporting the first package structure 62. The second package structure 74 also comprises a BGA (shown in FIG. 8) for transferring the input/output signals.

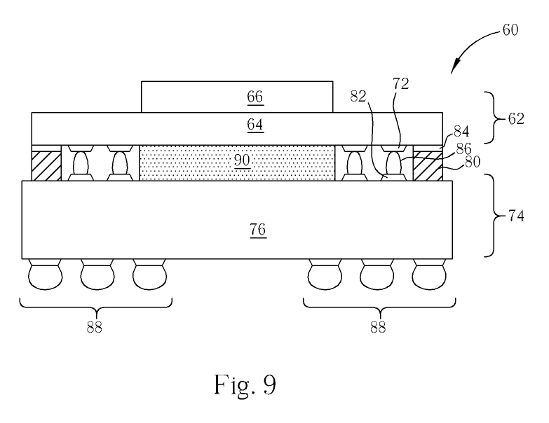

Next, please refer to FIG. 8. The semiconductor package structure 60 also comprises an adhesion layer 84 for adhering the first substrate 64 to the holder 80. The semiconductor package structure 60 further comprises a plurality of intermediate resilient conductive elements 86 formed in between the first substrate bonding pads 72 and the second substrate bonding pads 82. Each of the second substrate bonding pads 82 is electrically connected to the corresponding first substrate bonding pad 72 through at least one intermediate resilient conductive element 86. In other words, the electrical connection between the first package structure 62 and the second package structure 74 is provided by the intermediate resilient conductive elements 86. In addition, as shown in FIG. 9, the semiconductor package structure 60 can further comprise a moisture absorbing material 90, such as a moisture-adsorbing resin, for protecting the intermediate resilient conductive elements 86 from moisture, which affects electrical performance, depending on the standard of design and required function of the products.

It is noteworthy that the intermediate resilient conductive elements 86 are formed by metal wire bonds, each having a flexible part for contacting the first substrate bonding pads 72. The holder 80 comprising insulating material can be a ring holder surrounding the intermediate resilient conductive elements 86, the first substrate bonding pads 72, and the second substrate bonding pads 82. The ring holder 80 can comprise a plurality of openings depending on different demands. Such openings can be an injection hole for moisture absorbing material or sealing material or a dissipation hole. More significant, the holder 74 has a thickness substantially smaller than heights of the intermediate resilient conductive elements 86. When the first substrate 64 is adhered to the holder 74 by the adhesion layer 84, each of the first substrate bonding pads 72 will be against the flexible part of each intermediate resilient conductive element 86 and slightly press the intermediate resilient conductive element 86 down. Therefore the electrical connection between the first package structure 62 and the second package structure 74 is provided and assured.

As mentioned above, by using the chip holder to support the chip or the first package structure and by using the intermediate resilient conductive elements to absorb thermo-mechanical stress caused during operation, the semiconductor package structure provided by the present invention effectively avoids the problems of long filling process, incomplete filling, and air entrapment generated from the application of a sealing material. Furthermore, the semiconductor package structure also avoids problems such as failure of solder balls, cracking, and delamination caused by CTE mismatch without affecting the amounts and the density of the I/O terminals. Thus, the invention offers a highly reliable semiconductor package structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package structure comprising:
a semiconductor chip on which an electrical connection having a plurality of chip bonding pads there-within and a non-electrical connection region are defined;
a substrate having a plurality of substrate bonding pads corresponding to the chip bonding pads on a surface facing the semiconductor chip;
a chip holder formed on the substrate and corresponding to the non-electrical connection region for supporting the semiconductor chip; and
a plurality of intermediate resilient conductive elements formed in between the chip bonding pads and the substrate bonding pads for electrically connecting the semiconductor chip to the substrate.

2. The semiconductor package structure of claim 1, wherein the semiconductor chip is a flip chip (FC).

3. The semiconductor package structure of claim 1, wherein the chip holder has a thickness substantially smaller than heights of the intermediate resilient conductive elements.

4. The semiconductor package structure of claim 1, wherein the chip holder is a ring holder surrounding the intermediate resilient conductive elements, the chip bonding pads, and the substrate bonding pads.

5. The semiconductor package structure of claim 4, wherein the ring holder comprises a plurality of openings.

6. The semiconductor package structure of claim 1, wherein the chip holder comprises insulating material.

7. The semiconductor package structure of claim 1, wherein each of the substrate bonding pads is electrically connected to the corresponding chip bonding pad by at least one intermediate resilient conductive element.

8. The semiconductor package structure of claim 1, wherein the intermediate resilient conductive elements are wire bonds.

9. The semiconductor package structure of claim 8, wherein each of the intermediate resilient conductive elements further comprises a flexible part for contacting the chip bonding pads.

10. The semiconductor package structure of claim 1 further comprising a moisture absorbing material filled in between the semiconductor chip and the substrate.

11. A semiconductor package structure comprising:
a first package structure comprising:
a first substrate on which an electrical connection region having a plurality of first substrate bonding pads there-within and a non-electrical connection region are defined; and
at least a first chip on the first substrate;
a second package structure below the first package structure comprising:
a second substrate; and
at least a second chip formed on a surface of the second substrate;
a holder formed on the second substrate and corresponding to the non-electrical connection region for supporting the first package structure; and
a plurality of intermediate resilient conductive elements formed in between the first package structure and the second package structure for providing an electrical connection between the first package structure and the second package structure.

12. The semiconductor package structure of claim 11, wherein the electrical connection region and the non-electrical connection region are defined on a surface facing the second package structure.

13. The semiconductor package structure of claim 12, wherein the second substrate further comprises a plurality of second substrate bonding pads respectively corresponding to the first substrate bonding pads on the surface facing the first package structure.

14. The semiconductor package structure of claim 11, wherein the holder has a thickness smaller than heights of the intermediate resilient conductive elements.

15. The semiconductor package structure of claim 11, wherein the holder is a ring holder surrounding the intermediate resilient conductive elements, the first substrate bonding pads, and the second substrate bonding pads.

16. The semiconductor package structure of claim 15, wherein the ring holder further comprises a plurality of openings.

17. The semiconductor package structure of claim 11, wherein the holder comprises insulating material.

18. The semiconductor package structure of claim 11, wherein each of the first substrate bonding pads is electrically connected to the corresponding second substrate bonding pad by at least one intermediate resilient conductive element.

19. The semiconductor package structure of claim 11, wherein the intermediate resilient conductive elements are wire bonds.

20. The semiconductor package structure of claim 19, wherein each of the intermediate resilient conductive elements comprises a flexible part for contacting the first substrate bonding pad.

21. The semiconductor package structure of claim 11 further comprising a moisture absorbing material filled into the first package structure and the second package structure.
